(19) United States
(12) Patent Application Publication
(10) Pub. No.: US 2014/0069496 A1
(43) Pub. Date: Mar. 13, 2014

(54) Planar Plasmonic Device for Light Reflection, Diffusion and Guiding

(71) Applicants: Rana Biswas, Ames, IA (US); Vikram Dalal, Ames, IA (US)

(72) Inventors: Rana Biswas, Ames, IA (US); Vikram Dalal, Ames, IA (US)

(73) Assignee: Iowa State University Research Foundation, Inc., Ames, IA (US)

(21) Appl. No.: 14/079,036

(22) Filed: Nov. 13, 2013

Related U.S. Application Data
(62) Division of application No. 12/758,373, filed on Apr. 12, 2010, now abandoned.
(60) Provisional application No. 61/168,292, filed on Apr. 10, 2009.
(60) Provisional application No. 61/177,449, filed on May 12, 2009.

(51) Int. Cl. H01L 31/052

(52) U.S. Cl. CPC H01L 31/0527
USPC 136/256; 136/259

(57) ABSTRACT

A planar plasmonic device includes a first material layer having a surface configured to receive at least one photon of incident light. A patterned plasmonic nanostructured layer is disposed adjacent and optically coupled to the first material layer. The patterned plasmonic nanostructured layer includes a selected one of: a) at least a portion of a surface of the patterned plasmonic nanostructured layer includes a textured surface, and b) at least one compound nanofeature including a first material disposed adjacent to a second material within the compound nanofeature.

### CROSS-REFERENCE TO RELATED PATENT APPLICATIONS

This patent application is a divisional of co-pending U.S. non-provisional application application Ser. No. 12/758,373, entitled PLANAR PLASMONIC DEVICE FOR LIGHT REFLECTION, DIFFUSION AND GUIDING, filed Apr. 12, 2010, which claims priority to and the benefit of U.S. provisional patent application Ser. No. 61/168,292, entitled PLANAR PLASMONIC DEVICE FOR LIGHT REFLECTION, DIFFUSION AND GUIDING, filed Apr. 10, 2009, and U.S. provisional patent application Ser. No. 61/177,449, entitled PATTERNED PLANAR DEVICES AS INTERMEDIATE LIGHT DISTRIBUTING AND GUIDING LAYERS IN SOLAR CELLS, filed May 12, 2009, the teachings and disclosure of which are incorporated herein in their entireties by reference thereto.

### STATEMENT REGARDING FEDERALLY SPONSORED RESEARCH AND DEVELOPMENT

This invention was made in part with Government support under Grant Numbers NEU-0-99010-05 awarded by National Renewable Energy Laboratories (NREL); ECCS-0824091 awarded by the National Science Foundation (NSF); DE-AC36-08GO28308 awarded by the Department of Energy. The Government has certain rights in this invention.

### FIELD OF THE INVENTION

The invention relates to a planar plasmonic device in general and particularly to a planar plasmonic device employing a textured surface or a compound nanofeature.

### BACKGROUND OF THE INVENTION

The energy conversion efficiency and cost of a photovoltaic cell is directly related to the thickness of the absorbing layer. The importance of the thickness to conversion efficiency arises from the physics of the absorption process as described by Beer's Law. According to Beer's Law, the thicker the absorbing layer, the more light that is absorbed, and ultimately converted to electrical energy. Since absorption efficiency is also a function of wavelength, absorption over the entire solar spectrum should be considered when selecting and designing absorbers for solar cell applications.

In terms of economic efficiency, the cost of an absorbing layer is related to both the raw material cost and the manufacturing cost. While absorption efficiency increases with thickness, the cost of solar cell production increases with increased thickness. Further complicating the trade-offs between energy conversion efficiency and cost efficiency, many absorbers are made from scarce material resources, such as cadmium telluride. Therefore a reduction of material thickness can make possible an increase in total solar cell production numbers for the scarce resources.

Turning now to another engineering trade-off, in a typical crystalline silicon solar cell, recombination losses can be reduced by making the cell thin, leading to higher operating voltage. However, a thinner cell, having a thinner absorber, absorbs less light. With less light absorption, the photo-generated current is reduced, especially for long wavelength photons that are weakly absorbed and which would otherwise need a substantial amount of silicon for more efficient light absorption. In prior art structures, photons in a range of 400 nm to 500 nm may require a few micro-meters of Si for absorption of 99% of the energy, and infrared photons may require several hundred micro-meters to reach 99% absorption. Also, photons that are absorbed deep in the semiconductor must diffuse to the p-n junction to be collected, which increases the chance of recombination, leading to a lower light energy to electrical energy conversion efficiency.

What is needed, therefore, is a relatively thin solar cell structure that has a relatively low rate of recombination while more efficiently absorbing photons.

### SUMMARY OF THE INVENTION

In one aspect, a planar plasmonic device includes a first material layer having a surface configured to receive at least one photon of incident light. A patterned plasmonic nanostructured layer is disposed adjacent and optically coupled to the first material layer. The patterned plasmonic nanostructured layer includes a selected one of: a) at least a portion of a surface of the patterned plasmonic nanostructured layer includes a textured surface, and b) at least one compound nanofeature including a first material disposed adjacent to a second material within the compound nanofeature.

In one embodiment, the first material layer includes a silicon wafer.

In another embodiment, the planar plasmonic device includes an amorphous silicon layer with a superstrate structure.

In yet another embodiment, the patterned plasmonic nanostructured layer includes a plurality of nanofeatures having a shape selected from the group of shapes consisting of round, triangular, elliptical, cylindrical, square, rectangular, regular polygon, and irregular polygon.

In yet another embodiment, the patterned plasmonic nanostructured layer includes a plurality of nanofeatures having a selected one of physical feature of depression and physical feature of protrusion.

In yet another embodiment, the patterned plasmonic nanostructured layer includes a plurality of nanofeatures including patches of a metal.

In yet another embodiment, the patterned plasmonic nanostructured layer includes a patterned metal film.

In yet another embodiment, the patterned metal film includes a textured surface.

In yet another embodiment, the patterned metal film is disposed adjacent to a textured surface, the textured surface is provided on a selected one of a surface of the first material and a surface of the second material.

In yet another embodiment, the metal film includes a metal selected from the group consisting of silver, gold, copper, aluminum, nickel, titanium, chromium, silver alloy, gold alloy, copper alloy, aluminum alloy, nickel alloy, titanium alloy, chromium alloy, and a combination thereof.

In yet another embodiment, the first material and the second material of the at least one compound nanofeature are a first metal and a second metal., respectively.

In yet another embodiment, the patterned plasmonic nanostructured layer includes a plurality of nanofeatures formed on a surface of the first material layer and at least some of the plurality of nanofeatures are coated with a material that supports plasmon waves.

In yet another embodiment, the material that supports plasmon waves includes a metal selected from the group consisting of silver, gold, copper, aluminum, nickel, titanium, chromium, silver alloy, gold alloy, copper alloy, aluminum alloy, nickel alloy, titanium alloy, chromium alloy, and a combination thereof.

In yet another embodiment, the material that supports plasmon waves includes a transparent conductive oxide material.

In yet another embodiment, the transparent conductive oxide material is an oxide selected from the group consisting of indium-tin-oxide (ITO) and zinc oxide (ZnO).

In yet another embodiment, the planar plasmonic device further includes at least one solar cell layer electrically coupled within an integrated solar cell having an integrated solar cell positive terminal and an integrated solar cell negative terminal.

In yet another embodiment, the planar plasmonic device further includes a mirror.

In yet another embodiment, the planar plasmonic device further includes at least one wavelength conversion layer.

In yet another embodiment, the planar plasmonic device is configured as a selected one of a front layer of an integrated solar cell and a rear layer of the integrated solar cell.

In yet another embodiment, the planar plasmonic device includes a quarter-wave coating anti-reflective material.

The foregoing and other objects, aspects, features, and advantages of the invention will become more apparent from the following description and from the claims.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views:

FIG. 1 shows a cross sectional diagram of a prior art patterned semiconductor optical device;

FIG. 2 shows a cross section diagram of a planar plasmonic optical device;

FIG. 3 shows a plan view of the nanofeatures of the planar plasmonic device of FIG. 2;

FIG. 4A shows an illustration of one exemplary embodiment of a planar plasmonic device having a Lambertian surface;

FIG. 4B shows a cross section diagram of a planar plasmonic device having a patterned metal film with a textured surface;

FIG. 4C shows a cross section diagram of a self supporting planar plasmonic device;

FIG. 4D shows a cross section diagram of another self supporting planar plasmonic device illuminated on the opposite side as the device of FIG. 4C;

FIG. 5 shows one exemplary integrated solar cell having a planar plasmonic device as a back reflector;

FIG. 6A shows one exemplary integrated solar cell having a planar plasmonic device as a front reflector;

FIG. 6B shows one exemplary integrated solar cell having a first planar plasmonic device as a back reflector and a second planar plasmonic device as a front reflector;

FIG. 7 shows an exemplary cross-section diagram integrated solar cell having a planar plasmonic device with compound nanofeatures;

FIG. 8 shows a cross-section drawing of an integrated solar cell having a planar plasmonic device layer that replaces an anti-reflection coating;

FIG. 9 shows a cross-section diagram of an integrated solar cell a planar plasmonic device layer and a wavelength conversion layer;

FIGS. 10a and 10b (a) are schematic solar cell configuration with 2-d photonic crystal and (b) top view of 2-d photonic crystal layer

FIGS. 11a, 11b, 11c, and 11d are SEM images of the photonic crystal back-reflector taken after: (a) RIE etching and plasma cleaning; (b) 50 nm Ag evaporation; (c) 70 nm ZnO:Al sputtering; (d) a-Si:H deposition and ITO sputtering. All images taken at 25.000× magnification (1 μm scale);

FIG. 12 is an external quantum efficiency measurements for similar devices built on a stainless steel substrate, stainless steel substrate with 50 nm of Ag, and a c-Si wafer with a photonic crystal back-reflector. All measurements are normalized to 90% EQE;

FIG. 13 is a relative EQE enhancement ratios for the photonic crystal back-reflector versus a stainless steel substrate with and without a 50 nm silver layer. The PC shows an enhancement of 8 near 720 nm compared to the Ag reference;

FIG. 14 is absorption length of photons as a function of wavelength for a Si:H with bandgap Eg=1.6 eV. The band edge wavelength is indicated by the arrow;

FIGS. 15a and 15b (a) are schematics of silver back reflector with periodic hole array and (b) schematics of silver back reflector with periodic conical protrusions;

FIGS. 16a and 16b (a) are the variation of average absorption with lattice constant ‘a’ for metallic hole array with depth of 200 nm and R/a=0.25. (b) The variation of average absorption with hole diameter for hole depth of 300 nm and the variation with hole depth for R/a=0.25. The lattice constant is fixed at 700 nm; and

FIGS. 17a and 17b (a) The absorption enhancement with a metallic hole array with respect to the reference cell with a flat silver reflector and anti-reflective coating. (b) The absorption enhancement with metallic conical array with respect to the reference cell with a flat silver reflector and anti-reflective coating.

### DETAILED DESCRIPTION OF THE INVENTION

### Definitions

Integrated solar cell: We refer herein to a complete solar cell assembly of layers as an “integrated solar cell”. The term integrated solar cell, includes integrated structures made using both conventional semiconductor manufacturing methods, e.g. photolithography and vapor deposition, as well as layers manufactured in part or entirely by more recent fabrication methods, such as for example, nanofabrication methods.

Solar cell layer: The absorber of an integrated solar cell is referred to interchangeably herein as a “solar cell layer”. It is understood that one or more solar cell layers are electrically coupled within an integrated solar cell to provide an integrated solar cell electrical output voltage across an integrated solar cell positive terminal and an integrated solar cell negative terminal. In some embodiments a metal film present for optical reasons can also, but not necessarily, provide as an electrical connection to a solar cell layer.

Modification of light: Modification of light as used herein includes a change in direction of propagation and/or a change in wavelength of the light.

As described hereinabove, in prior art solar cell structures, there is a trade-off between the thickness of solar cell layers, particularly the thickness of the absorbing layer, the corresponding cost and availability of materials and conversion efficiency of light energy to electrical energy. The optical solution described hereinbelow which allows for less thick structures, while maintaining relatively high conversion efficiency is a new approach to light collection. The new approach, a planar plasmonic device, can be applied in light-collecting optics for solar cells. Our planar plasmonic device technology provides a new way to concentrate light and thereby increase efficiency, reduce material consumption, and lower the cost of solar cells. It is believed that planar plasmonic devices can be described at least part by light trapping. Light trapping is described in more detail hereinbelow in the section entitled, light trapping and theoretical background.

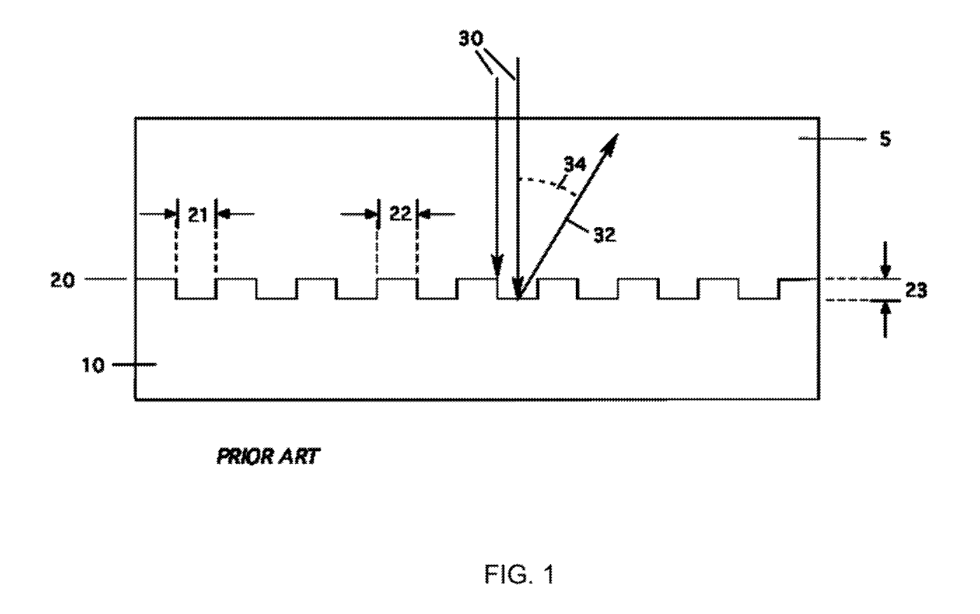

We begin by describing a semiconductor optical device of the prior art. FIG. 1 shows a cross sectional diagram of a prior art patterned semiconductor optical device. The device of FIG. 1 controls light by use of a diffraction grating at the back of a solar cell layer. An absorbing semiconductor 5 is patterned at the interface 20 between the absorbing semiconductor 5 and a material 10. Material 10 has a periodic pattern characterized by features having a depth 23, a width 21 and spacing 22. The periodicity of the grating is the sum of the dimensions width 21 and spacing 22. Incident photons represented by light rays 30 having a wavelength λ are reflected from the interface of absorber 5 and material 10 and undergo interference to produce photons represented by light ray 32 which are diffracted into an angle 34. Angle 34 is dependent on λ. The reflected photons represented by light ray 32 may be trapped if angle 34 is greater than the critical angle for total internal reflection (TIR). The critical angle for TIR depends on the index of refraction of material 5 and the surrounding media.

### Planar Plasmonic Device

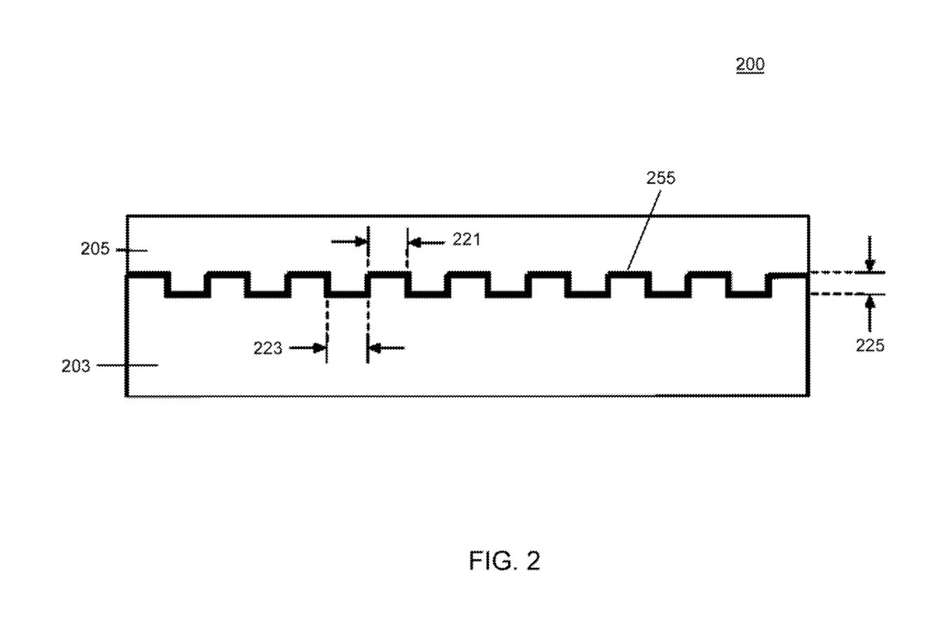

The prior art device of FIG. 1 can be improved by making use of plasmonic waves or surface plasmonic polaritons (SPP) to modify the wavelength dependence of the scattering angles and thereby attain an improvement in light trapping by TIR. FIG. 2 shows a cross section diagram of a planar plasmonic device 200 useful for light reflection, diffusion and guiding. Planar plasmonic device 200 has a metal film 255 at an interface between a material 203 and an absorbing material 205. The metallic film supports SPP modes that affect the propagation of light scattered at the interface. A thin film of plasmonic nanostructures (e.g. thin film 255, FIG. 2) can be made on any material that supports plasmon waves.

Alternatively, plasmonic nanostructures can be fabricated by patterning nanostructures in any suitable substrate including silicon and polymer substrates, and then coating the structures conformally with a material that can support plasmon waves. Materials that support plasmonic waves include electrically conductive materials made from gold, silver, chromium, titanium, copper, and aluminum or any suitable combination thereof. An electrically conductive material can also be made from a transparent conductive oxide. Examples of such materials are indium-tin-oxide (ITO) or zinc oxide (ZnO).

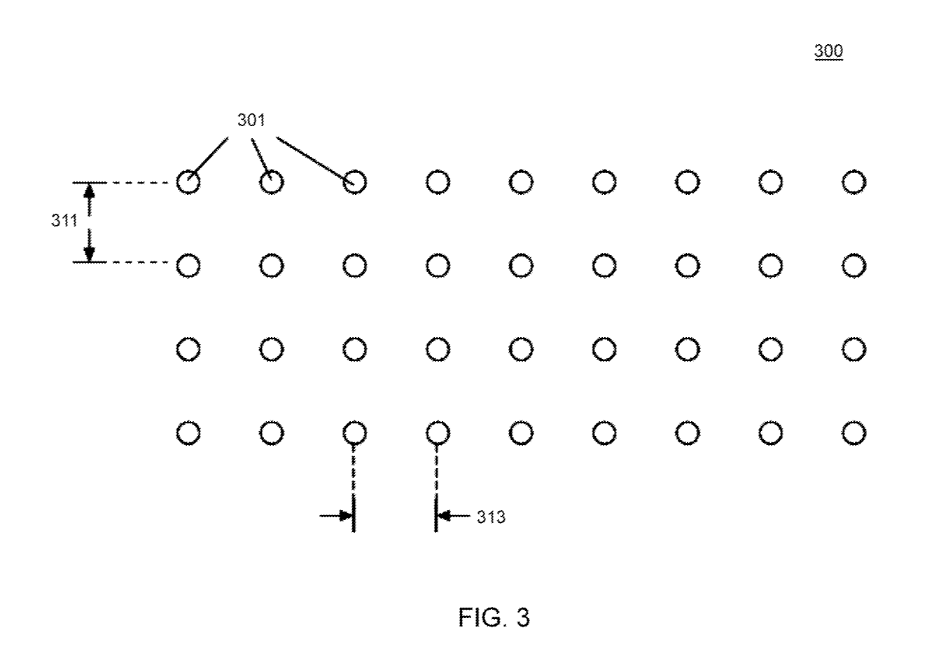

FIG. 3 shows a plan view of the nanofeatures of the planar plasmonic device of FIG. 2. Features 301 can be disposed in a regular array, such as an array having an inter-feature distance 311 along a first axis and an inter-feature distance 313 along a second axis not parallel to the first axis. Such nanofeatures can also be disposed in an irregular or random pattern. The inter-feature distance 311 and interfeature distance 313 can, for example, be on the order of the wavelength of light in the solar spectrum.

The nanofeatures of any of the embodiments of planar plasmonic devices described herein can be round, triangular, elliptical, cylindrical, square, rectangular, and/or of a regular or irregular polygon or any other suitable shape. While the nanofeatures are shown in FIG. 2 as depressions of depth 225, such nanofeatures can also be viewed as protrusions having a height 225. Such features can also be present as apertures through the film 255. Such features can also be present as patches, such as for example, isolated patches or islands of metal.

The physical nanofeatures can also include any suitable combination of two or more types of protrusions, depressions, apertures, or voids. For example, a pattern can be formed from a shape having an aperture surrounded by one or more protrusions. Or, a pattern can be formed from a shape having a void surrounded by a plurality of depressions. The thickness of the metallic film 255 is typically in a range of about 50 to 500 nm. The pattern of such a plasmonic layer can have a variety of pattern distributions as described herein. As described hereinabove, a metallic film 255 and/or nanofeatures on or in a thin film can be made from metals such as gold, silver, chromium, titanium, copper, and aluminum or any suitable combination thereof. An electrically conductive material can also be made from a transparent conductive oxide. Examples of such materials are indium-tin-oxide (ITO) or zinc oxide (ZnO).

Diffraction and/or plasmonic resonant structures as described hereinabove can be added on the top and/or bottom surfaces of a planar device layer to influence the propagation direction of the reflected and transmitted electromagnetic waves, such as light waves. Depending on a solar cell design, the propagation angle of the light entering various solar cell layers can have an optimum range related to the maximum optical absorption path in a solar cell layer. Diffraction-grating based surface plasmon resonance has been utilized in medical and biological research where metallic gratings are used to generate resonance between surface plasmons to diffract light at various angles. Plasmonic half-shell nanocups have also been demonstrated to receive selected electromagnetic waves and direct their propagation. These principles can be used in the design of light directing features on a plasmonic layer to guide the propagation direction of the reflected and transmitted light. In this way, by placing diffraction or plasmonic resonant structures on any of the planar devices described herein, we can further control the direction, and therefore the angle of light propagation within various solar cell layers to obtain a more optimal absorption of light. Alternatively, or additionally, one or more surfaces can be textured to provide Lambertian scattering.

### Planar Plasmonic Device Having Lambertian Surface

Optical devices such as those described hereinabove can be further improved by the addition of a Lambertian surface. A Lambertian surface is a surface that scatters light uniformly so that the apparent brightness of the surface to an observer is substantially the same regardless of the observer's angle of view. Lambertian surfaces have been utilized in many fields including solar cells to generate scattered light within the solar cell. Lambertian surfaces can be made, for example, by surface texturing. Depending on the surface texture process, in addition to Lambertian scattering, surface texturing can also provide scattering in preferred directions.

After the filing of our provisional applications whose priority is claimed, A. J. M. van Erven, et. al., “Periodic Texturing of Thin Film Silicon Solar Cell Superstrates”, 24th European Photovoltaic Solar Energy Conference, 21-25 Sep. 2009, Hamburg, Germany, described a combination of random texture and periodic structure for use in a solar cell that might improve the short circuit current of the solar cell through a combination of light diffraction and scattering effect.

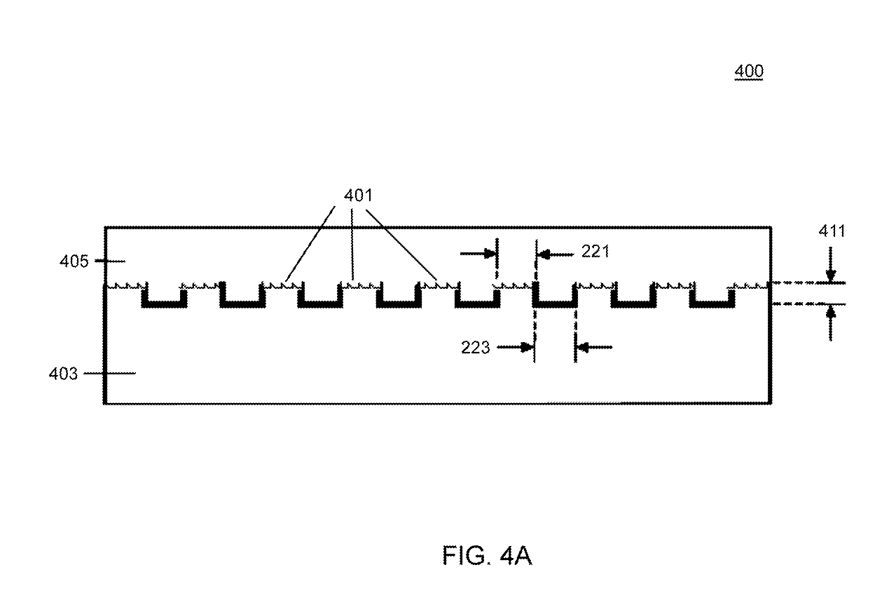

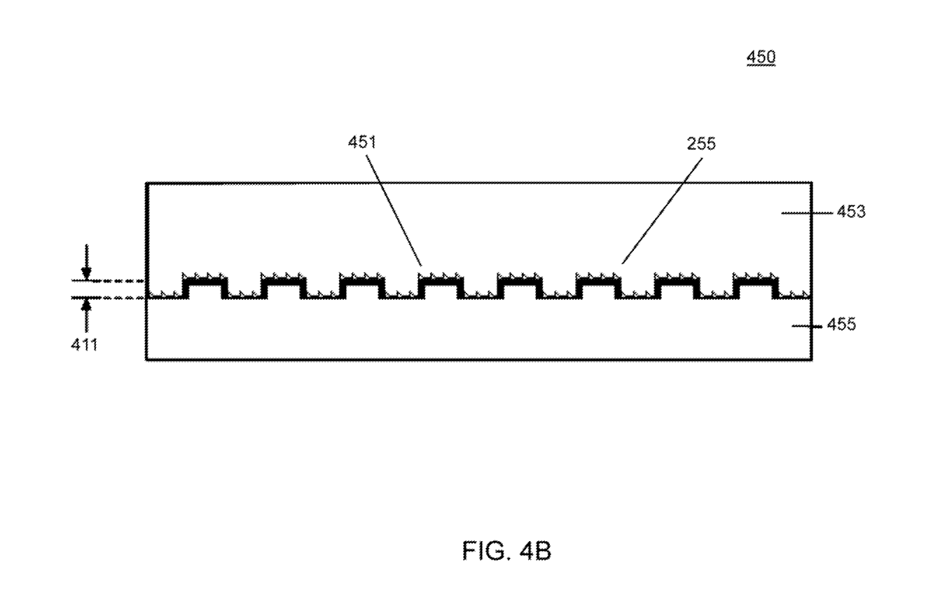

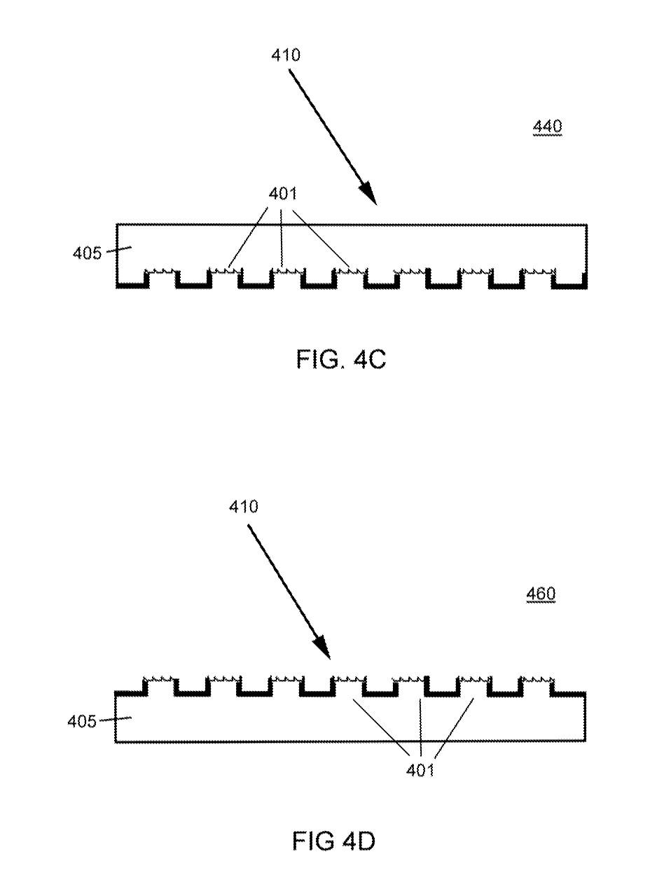

FIG. 4A shows an illustration of one exemplary embodiment of a planar plasmonic device 400 having a Lambertian surface. A surface of metal film 255 of the planar plasmonic device has been modified in a controlled manner to have a random or controlled texture 401. In some embodiments of the device of FIG. 4A, texture 401 can be formed in material 405, before the formation of layer 403. The structure of FIG. 4A is a plasmonic-textured device that takes advantage of both plasmonic and textured effects.

In prior art solar cell manufacture rough surfaces are avoided. Where a rough surface inadvertently results from one or more manufacturing steps, some sort of mechanical or chemical polishing step follows. However, according to the invention, a texture layer can be intentionally created, for example, by use of a sub micron lithography technique, or a more conventional roughening such as by plasma etching, by chemical methods, including chemical etching, vapor deposition that results in a rough surface, or other known roughening techniques. Such textures can have roughness features on the order of wavelengths of solar radiation. For example, it is believed that roughness features in a range of 10 nm to 500 nm can be used to make effective textured surface.

FIG. 4B shows another exemplary embodiment of a planar plasmonic devices having a Lambertian surface. In the embodiment of FIG. 4B, one of the surfaces of the patterned metal film 255 is textured. Such texturing can be accomplished by any suitable etching technique, including those described herein, or by coating a surface of patterned metal film 255 with a material that provides a textured surface.

In other embodiments of planar plasmonic devices, as shown by the cross-section diagram of FIG. 4C, a relatively thick first material 405 layer can be used to provide a self-supporting planar plasmonic device 440 structure illuminated by a light ray 410 that does not need a second material or substrate. Such embodiments can be made with a conventional several hundred micron thick silicon wafer (whether single crystal or polycrystalline) or by using a superstrate technology such as, for example, amorphous silicon deposited on glass. Such planar plasmonic devices combine the benefits of plasmons, diffraction and diffuse scattering. FIG. 4D shows a cross section diagram of another self supporting planar plasmonic device 460 illuminated by a light ray 410 on the opposite side as the device of FIG. 4C.

These “hybrid” planar plasmonic devices having both plasmonic interactions and conventional optical reflection, refraction, and/or scattering by textured surfaces, can be the most effective in reflecting or guiding the wavelength range of interest in a preferred angle for TIR.

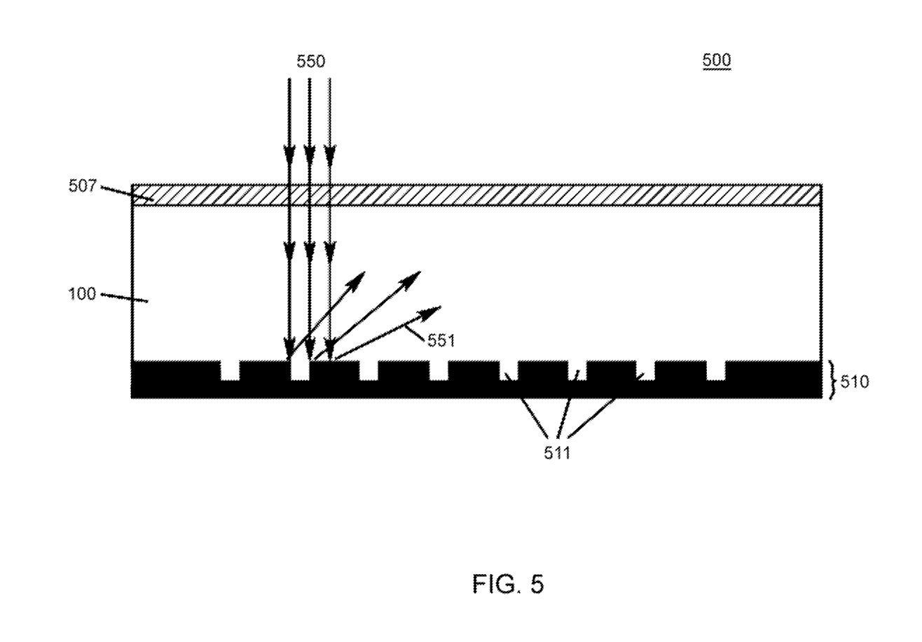

A planar plasmonic device can be incorporated into an integrated solar cell as a back-reflector and/or a front reflector to enhance light trapping in the solar cell layer. FIG. 5, for example, shows one exemplary integrated solar cell having a planar plasmonic device 510 as a back reflector. Integrated solar cell 500 includes solar cell layer 100, a conventional quarter wave anti-reflection coating 507 and a planar plasmonic device 510. Planar plasmonic device 510 includes a nanoarray of nanofeatures 511 at a second “back” surface of integrated solar cell 500.

Continuing with the embodiment of FIG. 5, in operation, light waves (photons of light) represented by light rays 550 incident on a first (“front”) surface of quarter wave anti-reflection coating 507 propagate to the planar plasmonic device 510 where the plurality nanofeatures 511 act to modify the light waves represented by light rays 550 so that after incidence on the planar plasmonic device 510, modified light waves, represented by light rays 551, propagate within the solar cell layer 100 towards a surface of quarter wave anti-reflection coating 507. The modification of the light waves, represented by light rays 551, is caused by a combination of surface plasmon effects, diffraction and reflection from the back nanoarray. Such modifications can include changes in direction as well as changes in wavelength.

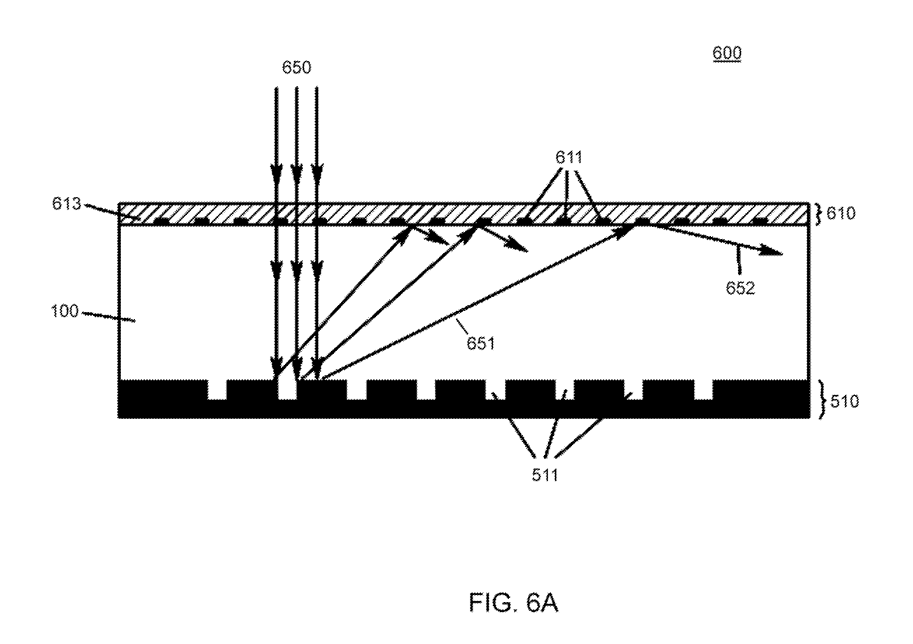

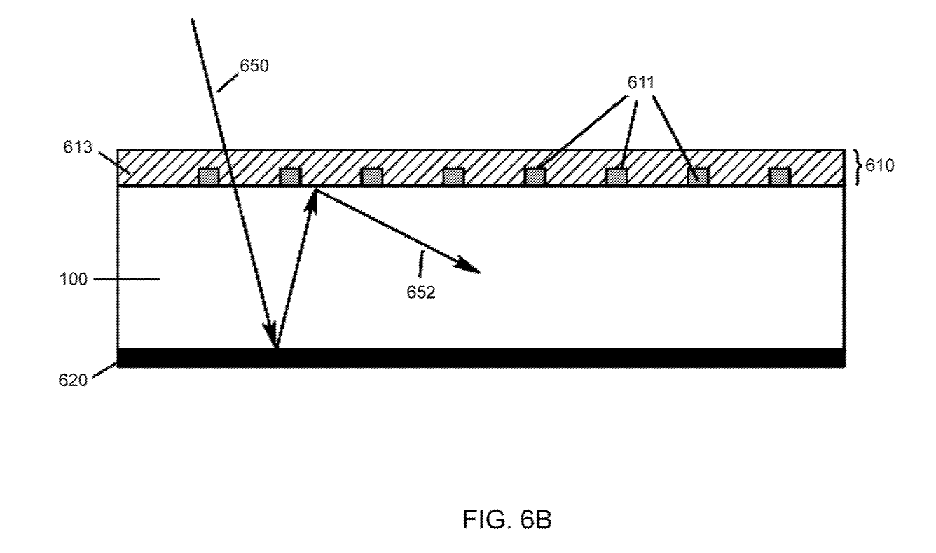

In addition to a planar plasmonic device on the “back” surface of an integrated solar cell, a planar plasmonic device can also be placed on the “front” surface. The addition of a planar plasmonic device on the front surface of an integrated solar cell can help to trap light propagating within the integrated solar cell. FIG. 6A shows an embodiment of one exemplary integrated solar cell having a planar plasmonic device on both the front and back of an integrated solar cell 600. The “back side” planar plasmonic device 510 can be substantially the same as planar plasmonic device 510 of FIG. 5. The “front” side planar plasmonic device 610 can include a plurality of nanofeatures 611 disposed within a quarter-wave coating 613. Light waves represented by light rays 650 are incident on the front of integrated solar cell 600. Light waves modified by planar plasmonic device 510 and represented by light rays 651 are again redirected through plasmonic interactions by planar plasmonic device 610 into modified light waves (e.g. modified with a new direction of propagation) represented by light rays 652. In this way the light wave can be more efficiently trapped in the solar cell layer 100.

FIG. 6B shows an embodiment of an integrated solar cell 650 having a “front” side planar plasmonic device 610, such as the planar plasmonic device 610 of FIG. 6A. In the embodiment of FIG. 6B, instead of the “back” side planar plasmonic device 510, there is a conventional mirrored layer 620.

### Planar Plasmonic Device Having Nanofeatuers Having Two Types of Metals

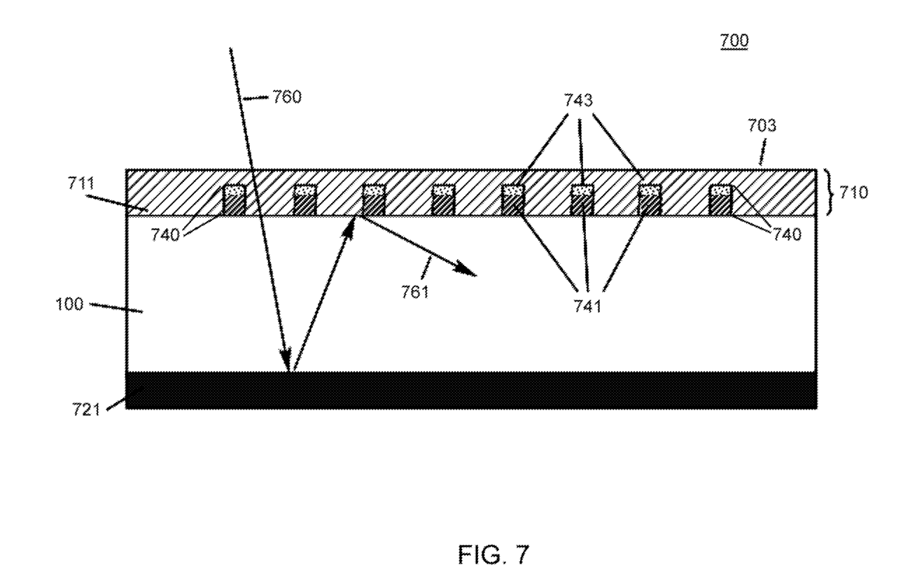

In another embodiment, it is believed that a planar plasmonic device having a nanoarray of compound nanofeatures having two different materials (e.g. two different types of metals or metal alloys) can advantageously change the plasmonic fields and improve the modification of light (e.g. direction or wavelength). A plurality of the compound nanofeatures has two or more different types of metals, such as in two or more distinct layers (as opposed to an alloy of two or more metals, although each type of distinct material can be made of a metal or metal alloy). As shown in the exemplary cross-section diagram integrated solar cell 700 of FIG. 7, a planar plasmonic device 710 made according to this aspect of the invention can also be used with a convention back surface reflector 721. A solar cell layer 100 is disposed adjacent to a reflector 721 at the back of integrated solar cell 700. Planar plasmonic device 710 includes a nanoarray of nanofeatures 740. A plurality of the nanofeatures 740 includes distinct sections of a first metal 741 and second metal 743. The nanoarray of nanofeatures 740 can be made using any of the materials and manufacturing techniques described herein. The difference of planar plasmonic device 710 over the previously described planar plasmonic devices is the compound nature of a plurality of the nanofeatures 740. The nanofeatures 740 can include the two types of materials in any suitable ratio by mass. For example, a nanofeature 740 can be made from equal masses or volumes of two types of materials, or there could be a relatively thick section of one type of material coated by a relatively thin surface coat of a second type of material.

In operation, photons, represented by light ray 760, pass through a first (“front”) surface 703 of the integrated solar cell 700 and propagate to the back side where some of the photons are reflected. Upon reaching planar plasmonic device 710 having a plurality of nanofeatures 740, the reflected ray is modified by the nanofeatures (e.g. modified in wavelength and/or direction) and continues to propagate within the cell as represented by light ray 761. In this way the light rays can be trapped within solar cell layer 100 of integrated solar cell 700.

### Improved Planar Plasmonic Device

As described hereinabove, a planar plasmonic device can be improved by the addition of a Lambertian surface. Also, as described hereinabove, a planar plasmonic device can be improved by use of a nanoarray of compound nanofeatures having two different materials (e.g. two different types of metals or metal alloys) that can advantageously change the plasmonic fields and improve the modification of light (e.g. direction or wavelength). Also, an improved a planar plasmonic device can include both a Lambertian surface and a nanoarray of compound nanofeatures having two different materials.

### Nanoarray in Place of an Anti-Reflection Coating

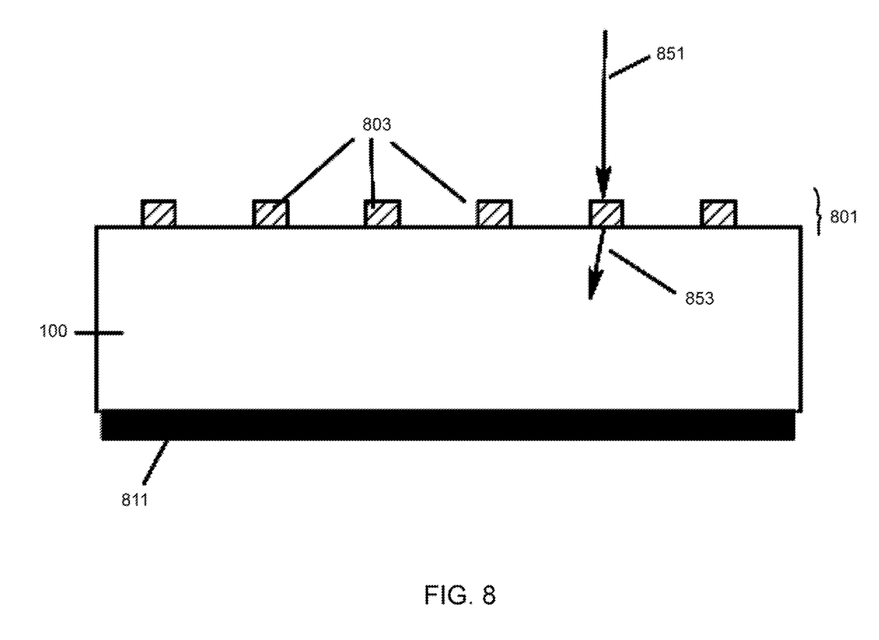

A nanoarray layer (such as for example, a planar plasmonic device layer) can also be used to replace an anti-reflection coating typically used on the “front” side of an integrated solar cell. FIG. 8 shows a cross-section drawing of an integrated solar cell 800 having a nanoarray 801 including nanofeatures 803. Nanoarray 801 is disposed on a first surface of a solar cell layer 100 at the “front” of integrated solar cell 800. In the exemplary embodiment of FIG. 8, there is also a back reflector or mirror layer, shown in FIG. 8 as surface reflector 811, disposed adjacent to the second surface of solar cell layer 100 at the back side of integrated solar cell 800.

In operation, the plurality of nanofeatures 803 on the front of integrated solar cell 800 absorb incoming photons of light represented by light ray 851 and re-emit photons of light represented by light ray 853. In addition to the anti-reflection, the nanoarray can also re-emit light 853 in a scattered direction. With a second (“back”) surface reflector 811, as shown in FIG. 8, some wavelengths of light can be substantially trapped within the absorber layer 100.

### Additional Wavelength Conversion Layers

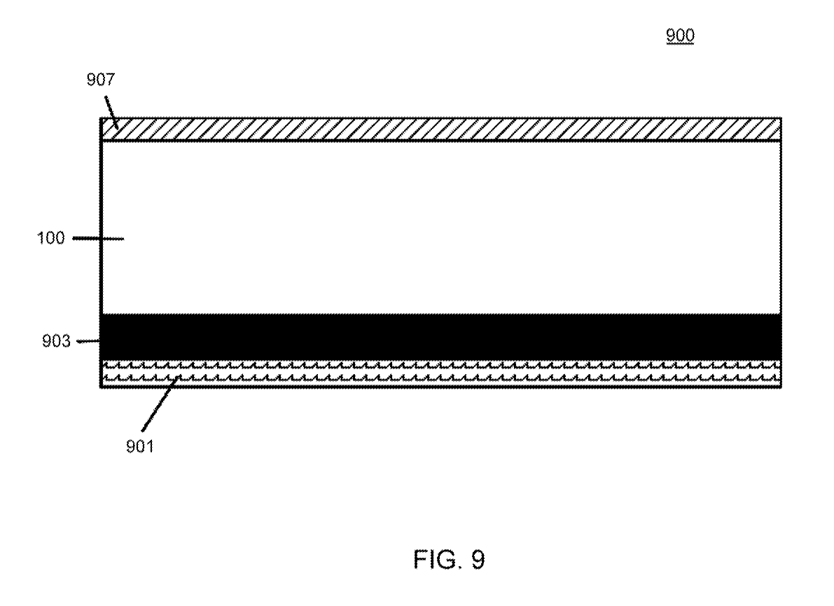

Embodiments of integrated solar cells including up and down conversion materials are also contemplated. For example, FIG. 9 shows a cross-section diagram of an integrated solar cell 900 that includes a nanoarray 901 (such as for example, a planar plasmonic device layer having a textured layer). Layer 903, a wavelength up-converting layer, is shown disposed between nanoarray 901 and a solar cell layer 100. A wavelength down-converting layer 907 can also be placed at the “front” of integrated solar cell 900. Suitable wavelength conversion layers have been described by the Lightwave Power Corporation, for example, in co-pending PCT Application No. PCT/US09/36815, entitled INTEGRATED SOLAR CELL WITH WAVELENGTH CONVERSION LAYERS AND LIGHT GUIDING AND CONCENTRATING LAYERS, filed Mar. 11, 2009, techniques of wavelength conversion layers in solar cells where the wavelength of an incident light can be converted to wavelengths more suitable for efficient absorption by particular photovoltaic (PV) layers of an integrated solar cell structure. The PCT/US09/36815 application is hereby incorporated herein by reference in its entirety for all purposes. Any of the integrated solar cell embodiments described herein, including integrated solar cells having nanoarrays (e.g. planar plasmonic devices) on the front, back, or both the front and the back of an integrated solar cell, can include one or more additional up or down converting layers, such as those described in the PCT/US09/36815 application.

### Multiple Layers

It is understood that there can be integrated solar cells having a plurality of planar plasmonic device layers. Such layers can, for example, cause modifications of selected wavelength ranges of light. It is also understood that a plurality of planar plasmonic device layers can be used in conjunction with a plurality of solar cell layers (“absorbers”), such as for example, where each of the plurality of solar cell layers are more efficient energy converters over different wavelength ranges. It is also understood that a plurality of planar plasmonic device layers can be used in conjunction with a plurality of wavelength conversion layers.

### Exemplary Methods and Materials of Manufacture

Dennis Slafer of the MicroContinuum Corporation of Cambridge, Mass., has described several manufacturing techniques and methods that are believed to be suitable for the manufacture of planar plasmonic devices and device layers as described herein. For example, U.S. patent application Ser. No. 12/358,964, ROLL-TO-ROLL PATTERNING OF TRANSPARENT AND METALLIC LAYERS, filed Jan. 23, 2009, published as US 2009/0136657 A1 describes and teaches one exemplary manufacturing process to create metallic films having a plurality of nanofeatures suitable for use in surface plasmon wavelength converter devices as described herein. Also, U.S. patent application Ser. No. 12/270,650, METHODS AND SYSTEMS FOR FORMING FLEXIBLE MULTILAYER STRUCTURES, filed Nov. 13, 2008, published May 28, 2009 as US 2009-0136657 A1, U.S. patent application Ser. No. 11/814,175, REPLICATION TOOLS AND RELATED FABRICATION METHOD AND APPARATUS, filed Aug. 4, 2008, published Dec. 18, 2008 as US 2008-0311235 A1, U.S. patent application Ser. No. 12/359,559, VACUUM COATING TECHNIQUES, filed Jan. 26, 2009, published Aug. 6, 2009 as US 2009-0194505 A1, and PCT Application No. PCT/US2006/023804, SYSTEMS AND METHODS FOR ROLL-TO-ROLL PATTERNING, filed Jun. 20, 2006, published Jan. 4, 2007 as WO 2007/001977, describe and teach related manufacturing methods which are also believed to be useful for manufacturing planar plasmonic devices and device layers and integrated solar cells having planar plasmonic devices as described herein. Each of the above identified United States and PCT applications is hereby incorporated herein by reference in its entirety for all purposes.

Laser interferometry is another manufacturing process that is believed to be suitable for the manufacture of planar plasmonic devices and other device layers as described herein. For example, in U.S. Pat. No. 7,304,775, Actively stabilized, single input beam, interference lithography system and method, D. Hobbs and J. Cowan described an interference lithography system that is capable of exposing high resolution patterns in photosensitive media and employing yield increasing active stabilization techniques. U.S. Pat. No. 7,304,775 is hereby incorporated herein by reference in its entirety for all purposes.

In one exemplary process, a substrate is coated with photoresist, and exposed to a laser source at defined regions that represent a complementary pattern of the desired nanopattern. Then the photoresist material is developed and the complementary nanopattern is formed in the photoresist material. This complementary nanopattern is then used as a template for the next stage in the process, which consists of deposition of the nanopatterned material (gold, silver, etc.) through a number of deposition techniques such as electron-beam evaporation and sputtering deposition. The remaining photoresist is then lifted off by chemical reagents, leaving behind the desired planar plasmonic device or device layer.

Turning now to materials useful for the manufacture of planar plasmonic devices and device layers, planar plasmonic devices and device layers can be made of any suitable conductor, such as for example, silver, gold, copper, aluminum, nickel, titanium, chromium, silver alloy, gold alloy, copper alloy, aluminum alloy, nickel alloy, titanium alloy, chromium alloy, or any combination thereof. Apertures (e. g., voids, holes, or nanofeatures) and/or media (e.g., dielectric media) can be present as a dielectric material, such as for example, a gas, air or silicon dioxide or a transparent conducting oxide such as tin oxide, zinc oxide, or indium tin oxide, or a semiconducting material such as silicon in any suitable form, such as for example, amorphous, crystalline, microcrystalline, nanocrystalline, or polycrystalline silicon. Copper indium gallium selenide (CIGS), and cadmium telluride (CdTe) are believed to be other suitable semiconducting materials. The apertures and/or media can be of different materials.

Other embodiments of planar plasmonic devices and device layers (not shown in the drawings) can include combinations of any of the above structures. Where nanofeatures of planar plasmonic devices and device layers include apertures, suitable apertures can take any form, including but not limited to, round or elliptical holes, slits, polygons, or irregular shapes. Resonant features can be of any suitable shape or morphology such as, but not limited to, ridges, bumps, depressions, and can be formed in any pattern including rings or gratings surrounding the aperture. The plurality of apertures as described in various embodiments can be periodic, non-periodic, or any combination thereof.

The shape and pattern of these intermediate light guiding nanostructures, whether they are apertures or nanoparticles, may vary and may comprise regular or irregular polygons, circles, ellipses or other geometric pattern. The thickness of the planar device 119 has a dimension that may vary from a dimension comparable to a skin depth of a photon of solar light or to several hundreds of nanometers. The pattern of the nanostructured planar device can include a plurality of shapes such as, rods, rectangles, triangles, linear ridges, circular ridges, spiral ridges, and stars. Each one of the shapes can also have a physical dimension of about a wavelength of light, such as in a wavelength range of the terrestrial solar spectrum (300 nm to 2000 nm).

Nanoarrays as described herein can include a regular array of nanoparticles or nano-apertures in a periodic pattern. Alternatively, there can be a random or non-periodic pattern of nanostructures. Nanoarrays can also include an array of nano-apertures, or alternatively a pattern of indentations that do not extend all the way through a thin film. A nanoarray can also include nanofeatures as an array of voids between two surfaces. Such physical features can also include any combination of two or more types of protrusions, depressions, apertures, or voids. For example, a pattern can be formed from a shape having an aperture surrounded by one or more protrusions. Or, a pattern can be formed from a shape having a void surrounded by a plurality of depressions.

In the below text, unless otherwise stated, all intermediate light guiding planar devices include the concept of a plain intermediate light guiding device or a nanopatterned-Lambertian device.

### Light Trapping and Theoretical Background

Embodiments of the invention include a patterned metallic planar layer to guide the direction of light of selected wavelengths so as to trap the photons within an absorbing layer adjacent to this planar metallic device, or to control the reflectance or other optical properties of a layer. By trap, we mean that a device or device layer causes light, once transmitted to an absorbing layer, to remain in the absorbing semiconductor or light guide until it is fully absorbed. By use of light trapping, the absorber can be made thinner, thus reducing cost. When light is trapped in a thin layer of an absorber, and made to propagate at a high angle compared to the surface normal vector, the thickness of the absorber becomes much less important to the conversion efficiency, and in some cases can improve the efficiency.

Thin films that can control the propagation direction of light of certain wavelengths are desirable in the solar industry since they can be applied to redirect and trap light that otherwise would escape the solar cell before absorption. The concept of light trapping has been known in the prior art for at least 30 years. One prior art approach is to use a randomly textured back reflector or random scattering by a front layer. Both approaches scatter light approximately uniformly into a plurality of angles, thereby increasing the path length of light within the solar cell.

Another prior art approach to light trapping comprises the use of conventional photonic crystals in a solar cell. Photonic crystals are composed of regions with a periodic modulation of the refractive index that only allows the propagation of light in certain regions. Photonic crystals are made from layers of dielectric or metallic materials and the modification of light propagation is a result of interference phenomena related to alternating high and low refractive index regions. A related way to control and direct the propagation of light is through diffraction gratings, in which grooves or lines are provided on a planar surface to diffract light to generate unique interference patterns, which then dictate the light propagation direction.

Recent studies have shown that light guiding has also been achieved by applying surface plasmonic polaritons (SPP), which are a transverse magnetic (TM) mode of an electromagnetic wave that propagates at the interface between a metal and a dielectric. Such studies used a prism to induce the coupling between the SPPs to photons, creating propagating modes and bandgaps. In other arrangements, diffraction-grating based surface plasmon resonances have been utilized in medical and biological research where metallic gratings were used to generate resonance between surface plasmons to diffract light at various angles. The change of the angle was used as an indicator to molecular interactions on the grating surface.

Some embodiments of the invention can use metallic 1-dimension (1-D) or 2-dimenision (2-D) plasmonic nanostructures to diffract and guide light in solar cells. These plasmonic nanostructures, also called metallic nanostructures, function as a diffraction grating or 2-D photonic crystal but do not necessary have the geometry a traditional diffraction grating has (linear grooves or rulings) or a photonic crystal has (composed of dielectric materials, having repeating alternating regions of high and low dielectric constants). These planar structures can diffract light at directions determined by the surface plasmon waves and the fixed geometry of the nanostructures. Such planar structures can be placed at the bottom or on the top of a solar cell, to redirect light back to the solar cell, or to guide light into the cell, increasing the absorbance of light within the cell. The planar structures can also be placed both on the front and rear surfaces of the absorber to provide the most benefits in guiding light into a solar cell, and maximizing the light trapping effect.

When light is incident on a planar plasmonic device, the scattering of the light waves is affected by three processes. First, the incident light undergoes typical diffraction on the nanostructured planar plasmonic device, similar to light incident on a metallic grating. Second, when a resonant condition as discussed below is met, the incident light excites SPPs. These SPPs propagate along the surface of the nanostructure. Surface features induce changes to the dispersion relations of SPPs owing to the interaction between the SPPs and the surface features. As a result, SPPs scatter into other SPPs propagating in other directions, or the SPPs decay by emitting photons. The SPPs and the resultant light scattering can be controlled by the design of the surface features. Mie plasmons can be excited as well when nanostructures include voids that are inside of the film at some distance from the surface. When Mie plasmons resonate with diffracted beams and SPPs, intensified diffraction is achieved.

The first scattering mechanism involves a plurality of incident wavelengths that can be efficiently diffracted at angles nearly parallel to the interface, generating well-known waveguiding modes. These wavelengths are strongly absorbed in the solar cell. The condition for this mechanism to occur is that the round-trip phase difference between the light waves from the bottom and top of the absorbing layer is an integral multiple of 2n.

The diffractive light-trapping mechanism is modeled by a simple analytical model. With an absorber thickness of d₂, all resonances require a roundtrip phase change 2mπ, so that the perpendicular component of the light wave-vector is k₊=πm/d₂. The wavelength of diffracted resonant mode is given by:

λ=2πn(λ)/\sqrt{Gₓ²+G_{y}²(mπ/d₂)²} (1)

where m is an integer, n is the wavelength dependent refractive index of the absorber layer and Gₓ, G_{y}, are the components of reciprocal lattice vectors (e.g. Gₓ=i(2 π/a); G_{y}=j(2 π/a) for a square lattice). The diffraction resonances occur for integer values of i, j and m and exhibit peaks in the absorption for wavelengths near the solar cell band edge. The peaks overlap and form the overall absorption enhancement. It is preferable to have several diffraction resonances within the wavelength window near the solar cell band edge, where the absorption length of photons is longer than the absorber layer thickness.

The second mechanism involves the generation of surface plasmons. To excite SPPs on a surface having periodic structures such as periodic array of holes, the incident light and the geometry of the structures need to satisfy the resonant condition described as:

$$λ = {a}_{0} \sqrt{\frac{{ɛ}_{1} {ɛ}_{2}}{{ɛ}_{1} + {ɛ}_{2}}} \qquad ( 2 )$$

where λ is the wavelength of the incident electromagnetic radiation; a₀ is the lattice constant; ε₁ and ε₂ are real portions of the respective dielectric constants for the metallic substrate and the surrounding medium in which the incident radiation passes prior to irradiating the metal film. For a non-periodic structure, the above equation may be modified to describe the resonant condition for a non-periodic structure. For example, where configuration comprises a single hole at the center of a single annular groove, the resonant condition may be described as:

$$λ = ρ \sqrt{\frac{{ɛ}_{1} {ɛ}_{2}}{{ɛ}_{1} + {ɛ}_{2}}} \qquad ( 3 )$$

where ρ denotes the radius of the annular groove from the centrally positioned aperture within the annular groove. Surface plasmons are waves in the periodic array that generate very strong electric fields in the absorber layer of the solar cell. The high electric field and concentration of light at resonant frequencies generates high absorption of incident wavelengths that satisfy this incident condition.

The coupling between SPPs and Mie plasmons can be effectively modified by tuning the geometry of the nanostructures such as the void diameter and/or the period of the void lattice or by the angle of the incident light. By the tuning the geometry of the nanostructures on a planar plasmonic device, one can couple or decouple the resonance between plasmons and incident and/or diffracted light of certain wavelengths, controlling the propagating direction and magnitude of the light.

One or multiple such planar plasmonic devices can be used in conjunction with an absorbing layer to guide the light into the layer, reflect light back to the absorbing layer effectively after they pass through the solar cell without absorption, and to trap light with the absorbing layer.

### Fabrication of Photonic Crystal Based Back-Reflectors for Light Management and Enhanced Absorption in Amorphous Silicon Solar Cells

With this understanding in mind, attention is now turned to the fabrication of photonic crystal based back-reflectors for light management and enhanced absorption in amorphous silicon solar cells.

As discussed, photonic crystal based back-reflectors are an attractive solution for light management and enhancing optical absorption in thin film solar cells, without undesirable losses. Embodiments of photonic crystal back-reflectors have been fabricated using photolithographic methods and reactive-ion etching. The photonic crystal back-reflector of one embodiment has a triangular lattice symmetry, a thickness of 250 nm, and a pitch of 765 nm. Scanning electron microscopy images demonstrate high quality long range periodicity. An a-Si:H solar cell device was grown on this back-reflector using standard PECVD techniques. Measurements demonstrate strong diffraction of light and high diffuse reflectance by the photonic crystal back-reflector. The photonic crystal back-reflector of this embodiment increased the average photon collection by ˜9% in terms of normalized external quantum efficiency, relative to a reference device on a stainless steel substrate with an Ag coated back surface.

A critical need for all solar cells is to maximize the absorption of the solar spectrum. Optical enhancements and light trapping is a cross-cutting challenge applicable to all types of solar cells. Traditionally, optical enhancements have involved use of anti-reflecting coatings coupled with a metallic back-reflector. Solar cell efficiencies are improved by textured metallic back-reflectors which scatter incident light through oblique angles, thereby increasing the path length of photons within the absorber layer. A completely random loss-less scatterer is predicted to achieve an enhancement of 4n² (n is the refractive index of the absorber layer), which has the value near 50 in a-Si:H. However the idealized limit of loss-less scattering is not possible to achieve in solar cells, and it is estimated that optical path length enhancements of ˜10 are achieved in practice.

Although this analysis can be applied to any semiconductor absorber, the focus here is on a-Si:H, where the optical constants have been well-determined. For a-Si:H with an energy gap of 1.75 eV typical of mid-gap cells, most photons with wavelengths below the band edge of 700 nm are absorbed. Short wavelength solar photons in the blue and green regions of the spectrum have absorption lengths less than 250 nm and are effectively absorbed within the thin absorber layer. However, the absorption length of photons grows rapidly for red light (λ>600 nm) and even exceeds 6-7 μm for photons near the band edge. These red and near-1R photons are very difficult to absorb in thin a-Si:H layers and light-trapping schemes are critical to harvest these long-wavelength photons. Similar physical considerations apply to the band-edge photons in c-Si absorber layers which are also difficult to harvest.

In one embodiment, therefore, a method for fabricating photonic crystal back-reflector structures is developed that diffract the near-band edge photons. The back-reflector solar cell of one embodiment includes a triangular lattice metallic photonic crystal, a-Si:H n-i-p solar cell device, and an indium tin oxide transparent top contact. The photonic crystal of this exemplary embodiment is etched into a patterned crystalline silicon wafer using reactive ion etching. Silver is then evaporated on the c-Si and used as both the back-reflector and back contact. Silver was chosen due to its high specular reflectance and low series contact resistance. A thin layer of zinc oxide is sputtered on the silver to prevent the diffusion of silver into the a-Si:H layer as well as silver agglomeration during high temperature a-Si:H processing. The a-Si:H n-i-p solar cell is deposited using standard plasma-enhanced chemical vapor deposition (PECVD) techniques. The thin ITO top contact is sputtered on the surface to complete the solar cell device of this exemplarily embodiment.

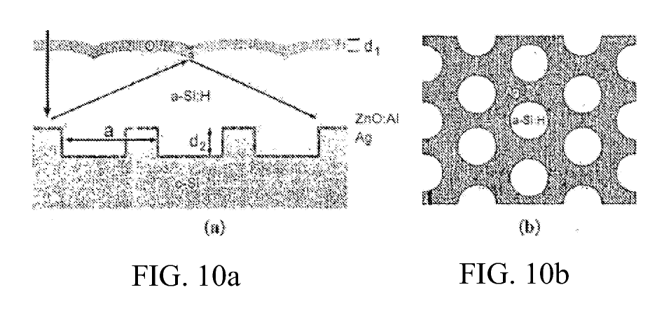

The metallic photonic crystal structure was optimized using simulation methods presented in previous work, where Maxwell's equations are solved in Fourier space using a rigorous scattering matrix method. Through the diffraction of near-band edge photons, it was found that the optimal absorption enhancement occurs with the following dimensions: a transparent ITO top contact with a thickness (d1) of 100 nm, photonic crystal grating depth (d2) of 250 nm, pitch (a) of 0.74 μm, and radius R/a ˜0.30. These dimensions were found for an a-Si:H n-i-p solar cell that includes a p-layer thickness of 20 nm, and intrinsic layer thickness 500 nm, and an n-layer thickness of 200 nm. These dimensions are shown in FIG. 10.

Crystalline silicon is used as the bulk photonic crystal structure for photolithography and etching purposes. The minimum feature size in the photonic crystal is approximately 300 nm, as defined by the spacing between etched c-Si cylinders. An ASML 193 nm step-and-repeat aligner is used to expose the photoresist with enough resolution to achieve the optimal dimensions. The photonic crystal is patterned into 480 nm of Rohm and Haas Epic 2135 photoresist and 80 nm of bottom antireflective coating. Since photoresist is the etch mask in this exemplary process, a sufficiently thick layer is required for reactive-ion etching.

A PlasmaTherm 700 series reactive-ion etching system was used to form the bulk c-Si photonic crystal in the patterned wafers. Dry etching is preferred over wet etching due to its greater amount of anisotropy and reproducibility between runs. Crystalline silicon etching is achieved with an 80:10 sccm CF₄:0² plasma, a chamber pressure of 50 mTorr, and RF power of 50 W. These parameters are the result of several experiments that investigated photoresist to c-Si etch selectivity and sidewall etch anisotropy. Once the etching is complete, oxygen plasma is used to remove the remaining photoresist and bottom antireflective coating.

A thin silver layer is deposited on the surface using, in one embodiment, thermal evaporation. It is advantageous to maximize the reflection of incident light that is not immediately absorbed within the intrinsic layer to determine the photonic crystal light-trapping enhancement. A 50 nm Ag layer was found to be sufficiently thick in one embodiment, with a transmission of <2% for near-band edge photons. The zinc oxide film thickness and sputtering parameters are ideal for forming a thin layer to encapsulate the Ag. A low temperature deposition prevents surface roughening due to silver agglomeration. Once the background chamber pressure reaches 1 μTorr, the ZnO:Al layer is sputtered at 150° C. The chamber pressure is held at 10 mTorr throughout this process with an argon ambient flow.

An a-Si:H n-i-p solar cell is deposited using the PECVD process. A typical device has an i-layer thickness of 250 nm and band-gap around 1.75 eV. Silicon carbide is used for the n-layer and is approximately 200-250 nm thick. DC sputtering is used to deposit the indium tin oxide top contacts. The sputtering parameters were developed to produce a 70 nm layer that is optimized for transparency, conductivity, and antireflective properties. Similar to the previous steps, the chamber background pressure is brought down to 1 μTorr before the substrate is heated to 225° C. During the deposition, the chamber pressure is held at 5 mTorr and a combination of argon and oxygen are introduced. Once the ITO sputtering is finished, the devices are annealed in atmosphere at a temperature of 200° C. for 20 minutes.

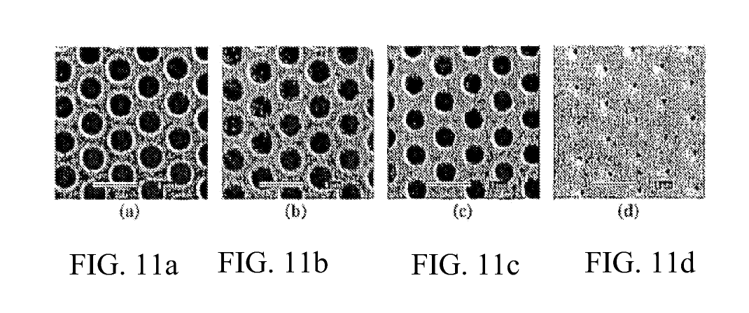

A scanning-electron microscope was used to characterize the back-reflector structure between each processing step. This allowed measurement of changes in the cylinder diameter from Ag and ZnO:Al depositing on the sidewalls. As shown in FIG. 11, R/a decreases from roughly 0.38 for bare c-Si, to 0.36 after Ag evaporation, and further to 0.32 after sputtering ZnO:Al. The lattice spacing was measured to be 765 nm on average and had long range order across the 12×12 mm die. In addition to measuring the photonic crystal, surface roughness of the back-reflector was investigated. The embodiment in FIG. 11b shows mild signs of silver agglomeration on the c-Si surface. The ZnO:Al sputtering appears to be slightly more uniform in the embodiment of FIG. 11c. The embodiment shown in FIG. 11d clearly shows conformal aSi:H growth within the photonic crystal cavities and the resulting non-uniform surface.

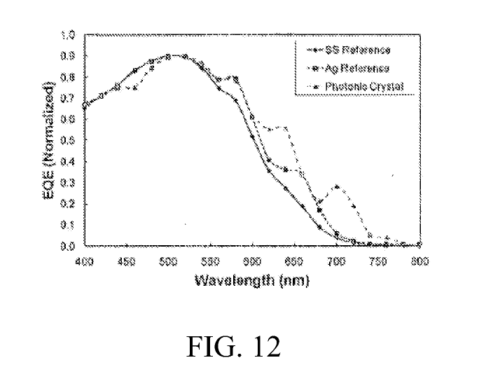

External quantum efficiency was measured to determine wavelength dependent collection enhancement from the photonic crystal back-reflector. EQE was determined by taking the ratio of photo-generated current from the a-Si:H solar cell devices to a reference c-Si photodiode with known quantum efficiency. These measurements were taken from 400-800 nm in 20 nm increments and are normalized to a maximum EQE of 90%. As shown in FIG. 12, the quantum efficiencies are similar for wavelengths below 550 nm where the wavelength-dependent photon absorption length is less than the i-layer thickness. The photonic crystal back-reflector device showed enhanced collection for wavelengths greater than 600 nm compared to the Ag and stainless steel reference devices.

An estimate of the solar cell short circuit current was also found by summing the product of device quantum efficiency and AMI 1.5 current at each measured wavelength. This is shown with:

$${J}_{SC , EQE} = {\sum }_{λ = 400 nm}^{800 nm} q Φ ( λ ) EQE ( λ )$$

where q is the unit charge of an electron in Coulombs and Φ is the AMI 1.5 solar flux in photons/sec/cm². This quantity is not intended to be a substitute for the I-V measure for J_{SC}, but rather a means of comparing quantum efficiencies that are weighted against the solar spectrum. The photonic crystal back-reflector of this embodiment showed a 9% improvement in EQE J_{SC} over the silver reference device and 18% over the stainless steel reference. These values are shown in Table 1.

TABLE 1
Short circuit current from relative EQE for a-Si:H
solar cells with different back substrates.

| Substrate | EQE J_{SC} (mA/cm²) |
|---|---|
| Stainless Steel | 11.21 |
| Stainless Steel with Silver | 12.17 |
| Photonic Crystal | 13.26 |

Theoretical simulations have been used to develop an a-Si:H n-i-p solar cell that utilizes a metallic photonic crystal back-reflector to increase the collection of near-band edge photons. As expected with photolithography, the PC lattice geometry was consistent across the 12×12 mm patterned die. Although the evaporated Ag was found to be relatively smooth, there was weak texturing across the entire sample that had features on the order of 100 nm. Reducing the roughness of the Ag film on c-Si will allow the creation of a Ag reference immediately next to the photonic crystal device of the embodiment discussed herein.

There is some variation in the structure parameters between the simulated and fabricated device. The R/a ratio was larger than expected after Ag evaporation, which can be attributed to isotropy during the RIE and possibly poor Ag sidewall coverage. R/a was closer to 0.3 after ZnO:Al sputtering but the structure was not simulated with this additional interface. A thinner absorption layer should result in greater EQE enhancement from the PC when compared to a smooth back-reflector.

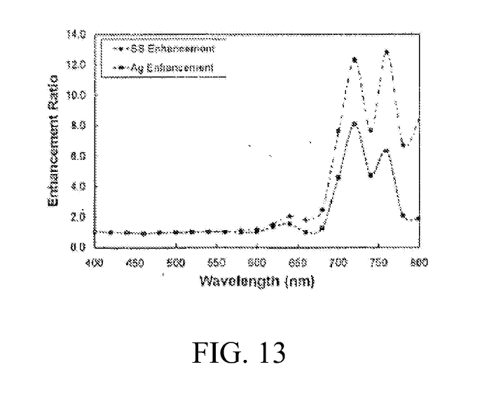

The ratio of the quantum efficiency for the photonic crystal back-reflector to that of a reference device clearly shows considerable enhancement at near-infrared wavelengths and is shown in FIG. 13. The most significant enhancement occurred near 720 nm, where the PC showed a factor of 8 improvement in collection over the Ag reference device. A secondary resonance was observed near 760 nm where the PC had an enhancement of ˜6 over the Ag reference. Significant enhancement was also seen with the stainless steel reference. This is expected as stainless steel has poor reflectance compared to Ag.

A process is developed and experimentally verified for embodiments of two dimensional metallic photonic crystal back-reflectors in a-Si:H solar cells. In a preferred embodiment, a photonic crystal pattern is etched into a c-Si wafer and then used as a back-reflector once Ag is evaporated and ZnO:Al is sputtered. This device shows a significant improvement in normalized EQE short-circuit current when compared to a stainless steel reference device that is half-coated with an Ag back-reflector. The EQE indicated that the PC back-reflector device enhanced near-band edge photon collection by a factor of 8 at 720 nm and 6 at 760 nm with respect to the Ag reference.

### Simulation of Plasmonic Crystal Enhancement of Thin Film Solar Cell Absorption

Attention is now directed to a simulation of plasmonic crystal enhancement of thin film solar cell absorption in accordance with an aspect of the invention.

As discussed hereinabove, light management and enhanced photon harvesting is a critical area for improving efficiency of thin film solar cells. Red and near infrared photons with energies just above the band edge have large absorption lengths in amorphous silicon and cannot be efficiently collected. It has been demonstrated that a photonic crystal back reflector involving a periodically patterned ZnO layer can enhance absorption of band edge photons.

Embodiments of a new plasmonic crystal structure enhance absorption in thin film solar cell structures. These plasmonic crystals include a periodically patterned metal back reflector with a periodic array of holes. In one embodiment, an amorphous/nanocrystalline silicon layer resides on top of this plasmonic crystal followed by a standard anti-reflecting coating. It has been found that such plasmonic crystal structures enhance average photon absorption by more than 10%, and by more than a factor of 10 at wavelengths just above the band edge, and should lead to improved cell efficiency. The plasmonic crystal of embodiments of the present invention diffracts band edge photons within the absorber layer, increasing their path length and dwell time. In addition there is concentration of light within the plasmonic crystal. Design simulations are performed with rigorous scattering matrix simulations for which both polarizations of light are accounted.

Photovoltaics and solar cells have been an active area for research and development, driven by the world's constantly increasing demand for power. Amorphous silicon (a-Si:H) is among the most developed material for thin film solar cells.

As discuss at length above, light trapping is the standard technique for improving the thin film solar cell efficiencies and harvesting the spectrum of incoming sunlight. The conventional light trapping schemes unitize a random textured Ag/ZnO back reflector that scatters light within the absorber layer and increases the optical path length of solar photons. However, those metallic back reflectors of silver coated with ZnO suffer from intrinsic losses from surface plasmon modes generated at the granular metal-dielectric interface. Periodic metallic gratings were also used to improve absorption of polymer based thin film solar cells. Recently, a light trapping scheme was developed for a-Si:H thin film solar cells, where the back reflector was replaced by two dimensional photonic crystal on top of distributed Bragg reflector (DBR). Photonic crystals have been a major scientific revolution in manipulating and guiding light in novel ways. The advantage of photonic crystals is to introduce diffraction, where the photon momentum (k) can be scattered away from the specular direction with (k″=k₁″+G), where G is a reciprocal lattice vector and k₁ is the incident wave-vector. The photonic crystal diffracts photons through oblique angles in the absorber layer, thereby increasing the path length and dwell time of photons.

Here a different approach to improving light trapping using metallic photonic crystals (or plasmonic crystals), rather than the dielectric photonic crystal used previously, is discussed. The dielectric DBR is replaced by flat silver mirror to reflect light specularly. The plasmonic crystal resides on this mirror. The plasmonic crystals can both diffract photons within the absorber layer and concentrate light to high intensities in regions of the cell. The diffraction mechanism of photonic crystals still applies here.

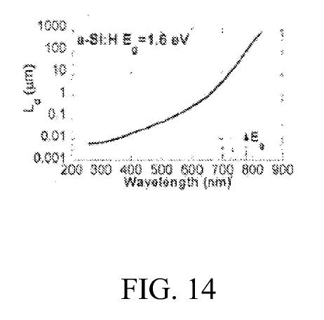

The typical thickness of a-Si:H solar cells is 250-500 nm and is limited by the minority carrier diffusion length. The photon absorption length (L_{d}) of a-Si:H with bandgap (E_{g}) of 1.6 eV is shown in FIG. 14. For wavelengths λ>600 nm, the absorption length exceeds 0.5 μm and approaches 100 μm near the band edge (λ_{g}=775 nm). As discussed above, it is extremely difficult to harvest these photons with a 500 nm absorber layer. Harvesting of the long wavelength photons is critical for improving short circuit currents (J_{sc}) and cell efficiencies.

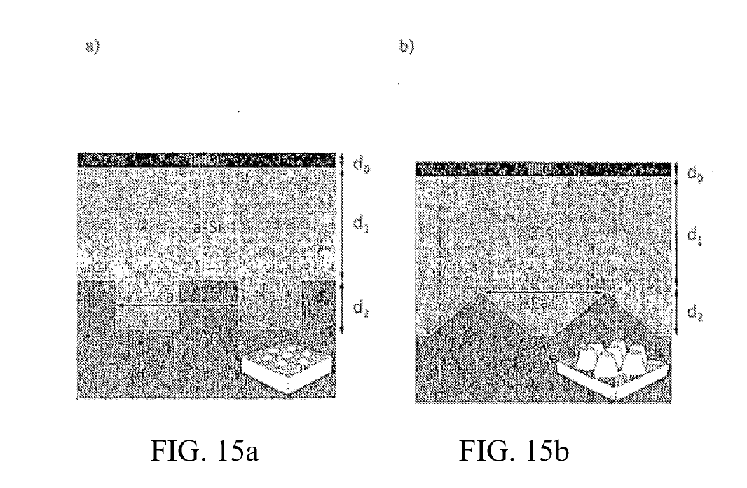

In the embodiment of a plasmonic crystal enhanced solar configuration shown in FIG. 15, there is 1) a top indium tin oxide (ITO) layer serving as antireflective coating and top contact (thickness d₀), 2) the absorber layer (thickness d₁), 3) the back reflector with silver plasmonic crystal structures. A thin layer of ZnO is deposited on the silver conformally. Two different embodiments of plasmonic back reflector structures are discussed here:

i) The first structure includes a Ag back reflector that has been patterned with a periodic array of holes. The depth of the holes is d₂ and they are filled with a-Si:H. The array of holes forms a triangular lattice two dimensional metallic photonic crystal with a lattice constant of ‘a’ (insert of FIG. 15a).

ii) the second structure includes conical protrusions of Ag on a base planar layer of Ag. In an embodiment used in simulations, the cones have flat tops. The height of the cones is d₂ and the space between the cones are filled with a-Si:H. The array of cones forms a triangular lattice two dimensional metallic photonic crystal with lattice constant of ‘a’ (FIG. 15b).

In a preferred embodiment, there is a deposition of a thin layer of ZnO between the amorphous silicon and silver to prevent diffusion of amorphous silicon into silver and make the interface smoother with less defects. Since a very thin ZnO layer is used (with thickness much smaller than the a-Si:H absorber layer or the wavelength of light), as a first approximation, we do not include the ZnO layer in the scattering matrix simulations.

Solar cell structures are simulated with a rigorous scattering matrix (S-matrix) method, where Maxwell's equations are solved in Fourier space and the electric/magnetic fields are expanded in Bloch waves. The structure is divided into slices along z direction. In each slice, the dielectric function ε(r) is a periodic function of x, y only and independent of z. Hence the dielectric function and its inverse are a Fourier expansion with coefficients ε(G) or ε⁻¹(G). A transfer matrix M in each layer can be calculated and diagonalized to obtain the eigenmodes within each layer for both polarizations. The continuity of the parallel components of E and H at each interface leads to the scattering matrices Sᵢ of each layer from which we obtain the scattering matrix S for the entire structure. Using the S-matrix, the reflection, transmission and absorption for the whole structure can be simulated. Since the solutions of Maxwell's equations are independent for each frequency, the computational algorithm has been parallelized where each frequency is simulated on a separate processor.

In the individual layers, realistic frequency dependent dielectric functions are used to include absorption and dispersion. The absorption and dispersion in ITO (that are appreciable below 400 nm) are ignored and a refractive index of 1.95 is assumed. For an aSi:H absorber with bandgap of 1.6 eV, the frequency dependent dielectric functions determined from spectroscopic ellipsometry for a-Si:H are used and analytically continued to the infrared. The experimental frequency dependent dielectric functions for Ag are used to account for absorption and dispersion.

In the case of a periodic hole array, the division of layers is straightforward. However, the division with no dielectric constant variation along z direction cannot be naturally done on the cone shaped gratings with flat tops. The sharp point is avoided so that very high fields at sharp points are absent. To work around this problem, each cone is approximated with a stack of 6 cylindrical disks with the same height and deceasing radii. With sufficiently large number of disks, a cone can be well simulated.

An absorber layer thickness of 500 nm, typical for single junction p-i-n solar cells, was used. In this discussion the absorption in the p-layer that typically reduces the blue response is ignored. The calculated total absorption in the i-layer is weighted by the AM 1.5 solar spectrum and integrated from 280 nm (λₘᵢₙ) to 775 nm (λ_{g}) to obtain the average absorption <A>:

$$〈 A 〉 = {\int }_{{λ}_{min}}^{{λ}_{g}} A ( λ ) \frac{d I}{d λ} d λ$$

where dI/dλ is the incident solar radiation intensity per unit wavelength. Average absorption <A> weighted by the solar spectrum is used as a figure of merit to systemically optimize each parameter of the solar cell structure to achieve the highest light trapping enhancement.

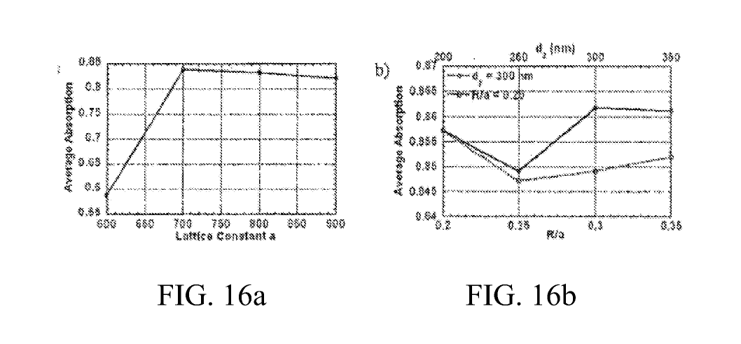

The thickness of the ITO layer is assumed to be 65 nm from previous simulations. By systematically varying parameters of the plasmonic crystal, back reflectors can be designed to maximize the average absorption of the solar cells. A back reflector with an array of holes having R/a=0.25 and hole depth d₂ of 200 nm is used to explore the dependence of average absorption on the lattice constant (FIG. 16a). The average absorption has strong dependence on the lattice constant. For a=700-800 nm, the average absorption is maximized. With lattice constant of 700 nm, the hole depth and R/a ratio are varied with the other parameters fixed. The average absorption variation (FIG. 16b) is optimized for an embodiment having a hole radius R/a=0.25 and a hole depth near 250 nm.

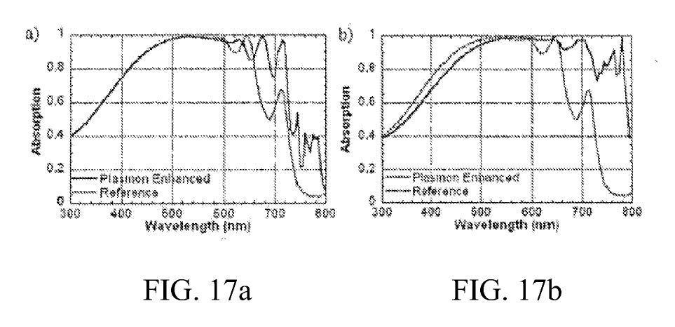

The design parameters of the back reflector with periodic cone protrusions (FIG. 15b) can be optimized in a similar fashion. It is found that the best absorption enhancement can be achieved in an embodiment with cone protrusions nearly touching each other (R/a˜0.5). The absorption of the solar cells with plasmonic crystal structures are compared with solar cell with same absorber and flat silver reflector (FIG. 17). Most of the enhanced absorption occurs near the band edge (600-775 nm), where photons have long absorption lengths. The plasmonic crystal generates modes of diffraction at these wavelengths, effectively increasing the path length or dwell time. Below 600 nm, the photonic crystal has little effect, since photons have absorption lengths smaller than the film thickness and are effectively absorbed within the a-Si:H absorber layer, without reaching the back surface. The fall-off in the absorption at short wavelengths is due to the anti-reflection layer being optimized for the green region of the spectrum.

In experimental solar cells, high absorption of the p-layer also decreases the absorption of blue photons. It is well known that the patterned back reflector will lead to conformal lattices in the top layer of the solar cell including at the a-Si:H/ITO interface. Preliminary calculations indicate that conformal patterns decrease the absorption enhancement.

Metallic photonic crystal back reflectors of the present invention generate significant increase of absorption and succeed in harvesting red and near infrared photons in amorphous silicon solar cells.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

Although the theoretical description given herein is thought to be correct, the operation of the devices described and claimed herein does not depend upon the accuracy or validity of the theoretical description. That is, later theoretical developments that may explain the observed results on a basis different from the theory presented herein will not detract from the inventions described herein.

While the present invention has been particularly shown and described with reference to the preferred mode as illustrated in the drawing, it will be understood by one skilled in the art that various changes in detail may be affected therein without departing from the spirit and scope of the invention as defined by the claims.

What is claimed is:

1. A photonic crystal back-reflector for diffracting near-band edge photons for use in a back-reflector solar cell, comprising:
a patterned plasmonic nanostructured layer forming a triangular lattice metallic photonic crystal; and
wherein the triangular lattice metallic photonic crystal is formed having at least one of a periodic array of holes in the metallic photonic crystal, or an array of cones on the metallic photonic crystal.

2. The back reflector of claim 1, comprises a patterned crystalline silicon wafer having silver deposited thereon.

3. The back reflector of claim 2, wherein a layer of zinc oxide is sputtered on the silver to prevent at least one of diffusion of silver into an a-Si:H layer of the solar cell and silver agglomeration during high temperature a-Si:H processing of the solar cell.

4. The back reflector of claim 2, wherein the silver deposited on the patterned crystalline silicon wafer has texturing thereon.

5. The back reflector of claim 4, wherein the texturing of the silver includes features on the order of 100 nm.

6. The back reflector of claim 1, wherein the photonic crystal has a minimum feature size of approximately 300 nm.

7. The back reflector of claim 1, comprising a flat silver mirror having a two-dimensional plasmonic crystal.

8. The back reflector of claim 7, wherein the flat silver mirror having a two-dimensional plasmonic crystal comprises a silver back reflector that has been patterned with a periodic array of nano-holes filled with a-Si:H forming a triangular lattice two dimensional metallic photonic crystal.

9. The back reflector of claim 7, wherein the flat silver mirror having a two-dimensional plasmonic crystal comprises an array of nanopillars formed as silver conical protrusions on a base planar layer of silver, the space between the conical protrusions being filled with a-Si:H, the array of conical protrusions forming a triangular lattice two dimensional metallic photonic crystal.

10. The thin film solar cell of claim 9, wherein the conical protrusions have flat tops.

11. A thin film solar cell, comprising a periodic photonic crystal based back reflector, the back reflector having a periodically textured array of nano-holes and/or nanopillars.

12. The thin film solar cell of claim 11, further comprising:
an a-Si:H n-i-p solar cell; and
a transparent top contact.

13. The thin film solar cell of claim 12, wherein the transparent top contact comprises indium tin oxide sputtered on the top surface of the a-Si:H n-i-p solar cell.

14. The thin film solar cell of claim 12, wherein the back reflector comprises a photonic crystal etched into a patterned crystalline silicon wafer having silver deposited thereon to serve as both the back reflector and back contact.

15. The thin film solar cell of claim 14, wherein a layer of zinc oxide is sputtered on the silver to prevent at least one of diffusion of silver into the a-Si:H layer and silver agglomeration during high temperature a-Si:H processing.

16. The thin film solar cell of claim 14, wherein the transparent top contact has a thickness of 100 nm, and wherein the back reflector has a photonic crystal grating depth of 250 nm, a pitch of 0.74 μm, a radius R/a ˜0.30, and wherein the silver is deposited to a layer thickness of 50 nm, and wherein the a-Si:H n-i-p solar cell includes a p-layer having a thickness of 20 nm, an intrinsic layer having a thickness of 500 nm, and an n-layer having a thickness of approximately 200-250 nm.

17. The thin film solar cell of claim 14, wherein the silver deposited on the patterned crystalline silicon wafer has texturing thereon.

18. The thin film solar cell of claim 17, wherein the texturing of the silver includes features on the order of 100 nm.

19. The thin film solar cell of claim 11, wherein the photonic crystal has a minimum feature size of approximately 300 nm.

20. The thin film solar cell of claim 11, wherein the back reflector comprises a flat silver mirror having a two-dimensional plasmonic crystal residing thereon.

21. The thin film solar cell of claim 20, wherein the back reflector structure includes a silver back reflector that has been patterned with a periodic array of nano-holes filled with a-Si:H forming a triangular lattice two dimensional metallic photonic crystal.

22. The thin film solar cell of claim 20, wherein the back reflector structure includes an array of nanopillars formed as silver conical protrusions on a base planar layer of silver, the space between the conical protrusions being filled with a-Si:H, the array of conical protrusions forming a triangular lattice two dimensional metallic photonic crystal.

23. The thin film solar cell of claim 22, wherein the conical protrusions have flat tops.
